(19) United States
(12) Patent Application Publication
(10) Pub. No.: US 2006/0231932 A1
(43) Pub. Date: Oct. 19, 2006

(54) ELECTRICAL PACKAGE STRUCTURE INCLUDING CHIP WITH POLYMER THEREON

(76) Inventors: Kai-Kuang Ho, Hsinchu City (TW); Kuo-Ming Chen, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/309,016

(22) Filed: Jun. 9, 2006

Related U.S. Application Data
(62) Division of application No. 10/711,540, filed on Sep. 24, 2004.

(51) Int. Cl. H01L 23/495

(52) U.S. Cl. 257/666

(57) ABSTRACT

An electrical package structure incorporating a chip with polymer thereon is described, including at least a package, a polymer and a molding compound. The package includes a carrier, at least one chip and multiple wires, wherein the chip is disposed on the carrier and the wires electrically connect the chip and the carrier. The polymer is disposed at the periphery of the chip possibly extending to the sidewalls of the chip and covering a portion of each wire near the chip, and the chip, the wires and the polymer are all enclosed in the molding compound. The polymer is preferably a stress buffer polymer like epoxy resin or polyimide, capable of inhibiting stress concentration at the periphery of the chip when the chip is subjected to repeated heat cycles for a long time. Therefore, the reliability of the electrical package structure can be improved.

### CROSS-REFERENCE TO RELATED APPLICATION

This is a divisional application of application Ser. No. 10/711,540, filed on Sep. 24, 2004 and is now pending. The entirety of the above-mentioned patent application is hereby incorporated by reference herein and made a part of this specification.

### BACKGROUND OF THE INVENTION

1. Field of the Invention

The present invention relates to structures of electronic devices. More particularly, the present invention relates to an electrical package structure including a chip with polymer thereon. The electrical package structure is suitably produced with a packaging process including wire-bonding operation.

2. Description of the Related Art

With the advances in technology and the raise of living standard, as well as the integration and ongoing growth of the 3C industry, applications of integrated circuits (IC) are more and more widespread in recent years. The production of IC devices can be divided into three stages including IC design, IC fabrication and IC package, wherein the IC fabrication includes wafer production, lithography processes, circuit formation and wafer dicing, etc. Each die divided from a wafer is electrically coupled to a carrier, such as, a leadframe or a circuit substrate, through wire bonding, flip-chip bonding or tab-automated bonding (TAB).

To fabricate a wire-bonding package structure, the die is bonded to the carrier at its back and is electrically coupled to the carrier through wire bonding, and then a molding compound is applied covering the die and the wires.

An electrical package structure of wire-bonding type usually includes a carrier, a chip, wires and a molding compound, wherein the carrier has many contacts thereon and the chip has an active surface with bonding pads thereon. The chip is disposed on the carrier with the active surface facing up, while the wires electrically connect the contacts and the bonding pads to electrically connect the chip and the carrier. In addition, the molding compound covers the die and the wires. The electrical package structure can protect the die from being damaged by moisture and dust from the outside, so that the performance of the chip is not degraded after long-term use. Moreover, the electrical package structure can provide electrical connection between the die and any external circuit, such as, a printed circuit board (PCB) or other package substrate. The electrical package structure can also dissipate the heat generated from the chip in use.

However, conventional electrical package structures frequently suffer from the “low-k peeling” problem described below, because low-k dielectric materials with lower strength and adhesion are widely used in replacement of SiO₂ in advanced processes. For example, the E-value (Young's modulus) of a low-k material is usually about 10 GPa, while that of SiO₂ is about 70 GPa. Therefore, delamination between low-k material layers and patterned circuit layers is easily caused in a temperature cycle test (TCT) that is one of many reliability tests conducted after the packaging process. More specifically, the delamination results from the stress concentration effect at the active surface of the chip, especially at the periphery of the active surface, which is caused by repeated thermal expansion and contraction of the package structure in the TCT.

Moreover, since the rigidity of low-k dielectric materials is generally lower than that of the material for forming the patterned circuit layers, such as, copper or aluminum alloy, delamination between the dielectric layers and the patterned circuit layers easily occurs when the wafer is being diced. The reliability of the electrical package structure is inevitably reduced if the degree of delamination is great.

### SUMMARY OF THE INVENTION

In view of the foregoing, this invention provides a chip with polymer thereon and an electrical package structure including the same, which is capable of reducing the stress at the periphery of the die to avoid stress concentration thereat.

This invention is also intended to inhibit delamination between the patterned circuit layers and the low-k material layers in a die to improve the reliability of the electrical package structure.

An electrical package structure incorporating a chip with polymer thereon of this invention includes at least a package, a polymer and a molding compound, wherein the package includes a carrier, a chip and wires. The chip has an active surface and is disposed on the carrier with the active surface facing up, and the wires electrically connect the chip and the carrier. The polymer is disposed at the periphery of the active surface of the chip extending to the sidewalls of the chip, and may further cover a portion of each wire near the active surface of the chip, so as to reduce the stress at the periphery of the active surface. In addition, the chip, the wires and the polymer are all enclosed in the molding compound.

Another electrical package structure incorporating a chip with polymer thereon of this invention includes at least a package, a polymer and a molding compound, wherein the package includes a carrier, multiple chips and wires. Each chip has an active surface, and the chips are sequentially stacked on the carrier. The wires electrically connect the chips and the carrier for their communication. The polymer is disposed at the periphery of the active surface of each chip extending to the sidewalls of the chip, and may further cover a portion of each wire near the chip, so as to reduce the stress at the periphery of the active surface of the chip. In addition, the chip, the wires and the polymer are all enclosed in the molding compound.

This invention also provides a chip with polymer thereon that is suitably disposed on a carrier. The chip has an active surface, and the polymer is disposed at the periphery of the active surface of the chip extending to the sidewalls of the chip, so as to reduce the stress at the periphery of the active surface of the chip.

According to an embodiment of this invention, the chip nearest to the carrier can be bonded to the carrier through flip-chip bonding, but the other chips through wire bonding. The chips can also be coupled with each other through wire bonding.

According to another embodiment of this invention, each of the chips can be bonded to the carrier through wire bonding. The chips can also be coupled with each other through wire bonding in this case.

According to still another embodiment of this invention, the above multi-chip electrical package structure may further include at least one spacer disposed between the chips. The spacer may include a dummy chip.

According to some embodiments of this invention, the polymer may further cover a portion of the carrier. Alternatively, the polymer may cover a portion of each wire near the chip and a portion of the carrier simultaneously.

Moreover, the polymer may be formed as a ring covering the whole periphery of the active surface of the corresponding chip, as strips covering two opposite edges of the active surface, or as multiple pieces covering four corners of the active surface.

In addition, according to a preferred embodiment of this invention, the above polymer is a stress buffer polymer, such as, epoxy resin or polyimide.

Since the polymer as a stress buffer is disposed at the periphery of the active surface of the chip, the stress concentration effect thereat, especially the stress concentration at the low-k dielectric layers in the chip, can be reduced. Therefore, delamination between patterned circuit layers and low-k dielectric layers can be inhibited to improve the reliability of the electrical package structure.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A illustrates a local cross-sectional view of a chip with polymer thereon according to a first embodiment of this invention.

FIG. 1B illustrates the top view of an example of the chip with polymer thereon according to the first embodiment of this invention, wherein the polymer is shaped as a ring covering the whole periphery of the active surface of the chip.

FIG. 1C illustrates the top view of another example of the chip with polymer thereon according to the first embodiment of this invention, wherein the polymer is shaped as multiple strips covering two opposite edges of the active surface of the chip.

FIG. 1D illustrates a local top view of still another example of the chip with polymer thereon according to the first embodiment of this invention, wherein the polymer is shaped as blocks covering four corners of the active surface of the chip.

FIG. 2A illustrates a cross-sectional view of an electrical package structure incorporating a chip with polymer thereon according to a second embodiment of this invention.

FIG. 2B illustrates a cross-sectional view of an electrical package structure incorporating a chip with polymer thereon according to a third embodiment of this invention.

FIG. 2C illustrates a cross-sectional view of an electrical package structure incorporating a chip with polymer thereon according to a fourth embodiment of this invention.

FIG. 3A illustrates a cross-sectional view of an electrical package structure incorporating a chip with polymer thereon according to a fifth embodiment of this invention.

FIG. 3B illustrates a cross-sectional view of an electrical package structure incorporating a chip with polymer thereon according to a sixth embodiment of this invention.

FIG. 3C illustrates a cross-sectional view of an electrical package structure incorporating a chip with polymer thereon according to a seventh embodiment of this invention.

### DESCRIPTION OF THE PREFERRED EMBODIMENTS

### First Embodiment

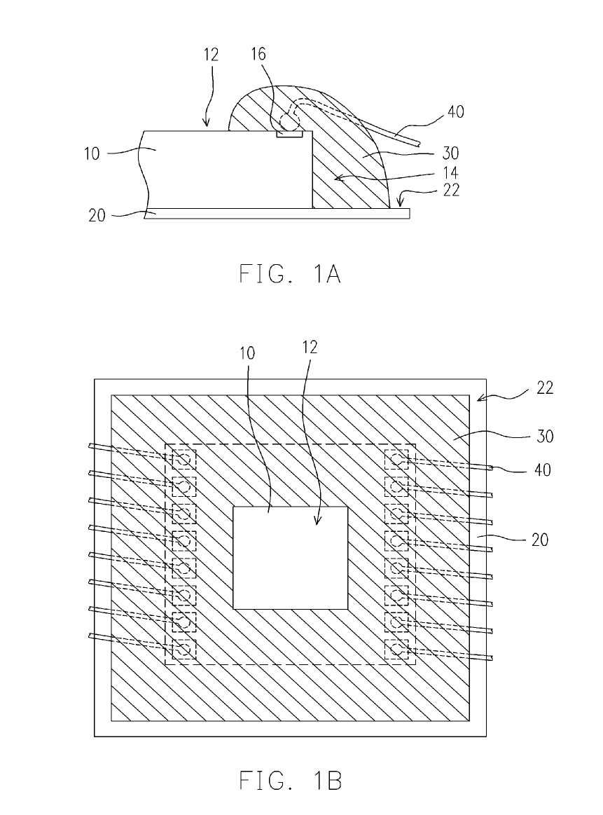

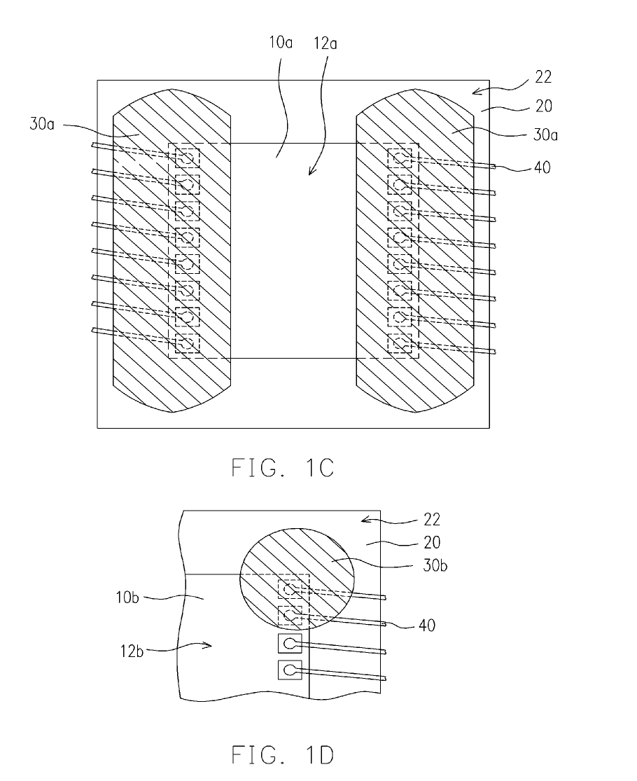

FIG. 1A illustrates a local cross-sectional view of a chip with polymer thereon according to the first embodiment of this invention. FIG. 1B illustrates the top view of an example of the chip with polymer thereon, wherein the polymer is shaped as a ring covering the whole periphery of the active surface of the chip. Referring to FIGS. 1A and 1B, the chip 10 has an active surface 12 with bonding pads 16 thereon, and is suitable for fabricating an electrical package structure of wire-bonding type. The chip 10 is disposed on a carrier 20, which may be a die pad of a leadframe, or a circuit substrate. The two ends of each wire 40 are bonded to a bonding pad 16 on the chip 10 and a contact (not shown) on the carrier 20, respectively, for electrically connecting the chip 10 and the carrier 20.

Particularly, a polymer 30 is applied, preferably by using a dispenser, covering the whole periphery of the active surface 12 of the chip 10 and a portion of each wire 40 near the active surface 12 of the chip 10. The polymer 30 is preferably a stress buffer polymer, such as, epoxy resin, polyimide or the like. The polymer 30 can reduce the stress at the periphery of the active surface 12 of the chip 10, especially the stress at the periphery of the low-k dielectric layers (not shown) in the chip 10, that is generated due to long-term thermal expansion/shrinking. In this embodiment, the polymer 30 can be formed as a ring covering the stress concentrated regions, for example, the four corners of the active surface 12 of the chip 10, to reduce the stress at the periphery of the active surface 12 of the chip 10. The polymer 30 may extend to the cutting surfaces (sidewalls) 14 of the chip 10 adjacent to the active surface 12, and may even extend to cover the whole sidewalls 14 of the chip 10, so as to effectively inhibit delamination in the chip 10. The polymer may further cover a portion of the surface 22 of the carrier 20 to alleviate the continuously varying stress between the chip 10 and the carrier 20.

FIG. 1C illustrates the top view of another example of the chip with polymer thereon according to the first embodiment of this invention. Referring to FIG. 1C, the polymer 30 may alternatively be formed as strips 30a covering two opposite edges of the chip 10a. Similarly, the polymer strips 30a may simply cover two opposite edge portions of the active surface 12a of the chip 10a, or extend to the sidewalls of the chip 10a or further extend to cover a portion of the surface 22 of the carrier 20.

FIG. 1D illustrates a local top view of still another example of the chip with polymer thereon according to the first embodiment of this invention. Referring to FIG. 1D, the polymer 30 can be formed as multiple pieces 30b covering the corners of the active surface 12b of the chip 10b. Similarly, the pieces 30b of polymer may simply cover the four corners of the active surface 12b of the chip 10b, or extend to the sidewalls of the chip 10b or further extend to cover a portion of the surface 22 of the carrier 20.

The amount of the polymer shaped as a ring, strips or pieces can be easily controlled by adjusting the discharge amount of the dispenser, so that the polymer is applied merely on the active surface and the sidewalls of the chip without extending to the carrier. Moreover, the molding compound can be applied to cover the whole active surface of the chip, the portions of the wires not covered by the polymer, and the carrier not covered by the polymer. The molding compound can protect the chip from being damaged by external force and prevent the wires from being exposed in the atmosphere and degraded therefore.

It is noted that though the chip and the wires are all covered by the low-priced molding compound in prior art, the stress buffer effect of the molding compound is still insufficient. To obtain better stress buffer effect, this invention applies a polymer having better stress buffer effect to the whole periphery, two opposite edges or four corners of the chip, and then cover the chip, the wires and the polymer with the molding compound. Since the applied amount of the polymer is much less than that of the low-priced molding compound, the manufacturing cost can be well controlled to make a balance between the stress buffer effect and the cost.

To demonstrate the effects of this invention, the chip with polymer thereon is compared with a conventional chip for the shear stress at their corners, wherein each chip is based on a silicon substrate and the polymer is a stress buffer polymer like epoxy resin or polyimide. When the chip size is 8 mm×8 mm, the shear stress at the corners of a conventional chip is 25.52 kg/cm², while that at the corners of the chip with polymer thereon is 19.12 kg/cm². When the chip size is 16 mm×16 mm, the shear stress at the corners of the conventional chip is 33.21 kg/cm², while that at the corners of the chip with polymer thereon is 25.61 kg/cm².

Accordingly, as compared with a conventional chip, the shear stress at the corners of the chip with polymer thereon of this invention is lower by about 25%, which means that the stress less concentrates at the corners of the chip and distributes more evenly. Therefore, the degree of delamination between the patterned circuit layers and the dielectric layers in the chip can be reduced to improve the reliability of the chip. Moreover, since the applied amount of the polymer is much less than that of the low-priced molding compound, the manufacturing cost can be well controlled to make a balance between the stress buffer effect and the cost.

In addition, the chip with polymer thereon of this invention is suitably used to fabricate an electrical package structure of leadframe or substrate type. There can be one or more, possibly up to seven, such chips stacked in one package structure, but only the cases with one or more chips disposed in one package structure of leadframe or substrate type are described in the following embodiments. Since various multi-chip package structures have been well developed, the cases with more than two chips can be easily understood through the descriptions of the following embodiments.

### Second Embodiment

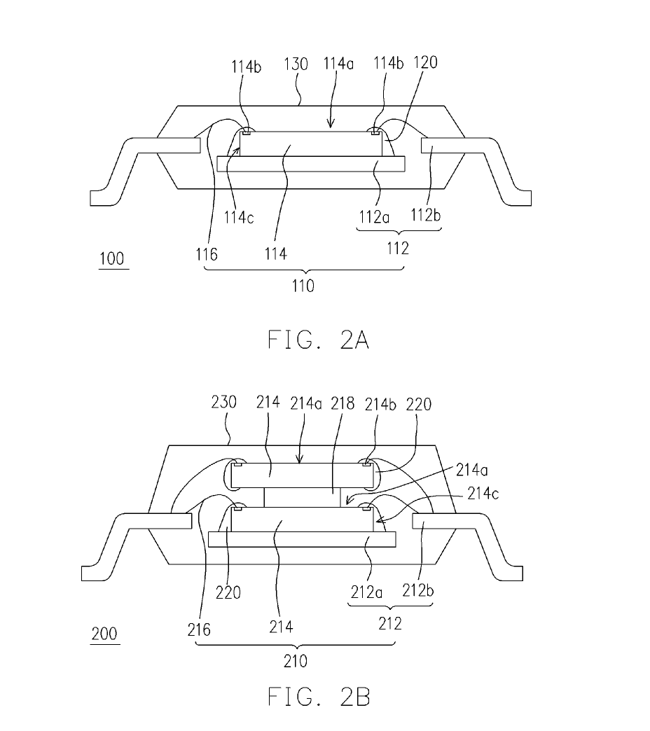

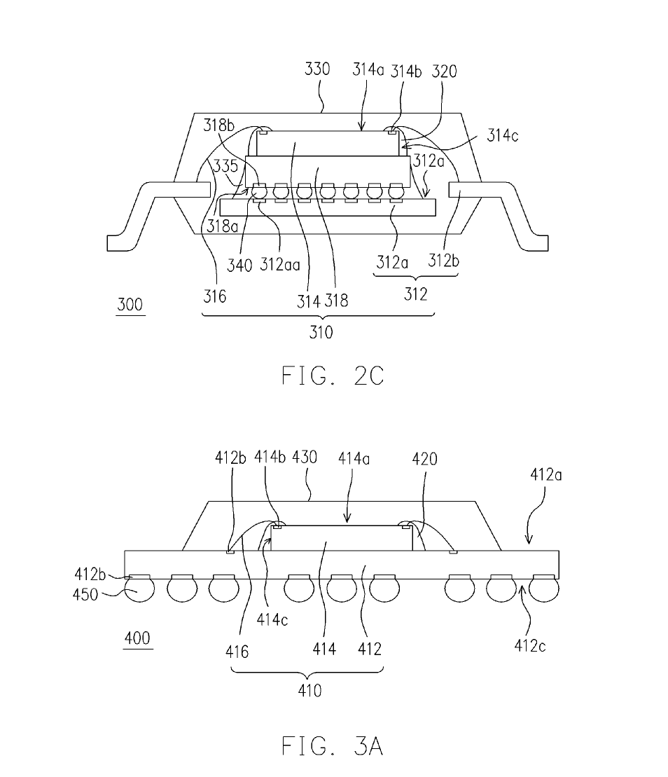

FIG. 2A illustrates a cross-sectional view of an electrical package structure incorporating a chip with polymer thereon according to the second embodiment of this invention. Referring to FIG. 2A, the electrical package structure 100 includes a package 110, a polymer 120 and a molding compound 130, wherein the package 110 includes a carrier 112, a chip 114 and wires 116. The carrier 112 is a leadframe including a die pad 112a and many leads 112b, for example. The chip 114 is fixed onto the die pad 112a, and has an active surface 114a with bonding pads 114b thereon. The two ends of each wire 116 are bonded to a lead 112b and a bonding pad 114b, respectively, to electrically connect the lead 112b and the bonding pads 114b, so that the chip 114 can be coupled with the leads 112b.

The polymer 120 is disposed at the periphery of the chip 114, in the form of a ring, strips or pieces, possibly by using a dispenser, so as to alleviate the stress thereat. The polymer 120 may cover some or all bonding pads 114b on the chip 114 and a portion of each wire 116 near the covered bonding pads 114b, and may further extend to sidewalls 114c of the chip 114 and even the surface of the die pad 112a to alleviate the stress around the chip 114. The molding compound 130 is disposed covering the chip 114, the wires 116 and the polymer 120 for their protection. The polymer 120 preferably has a stress buffer effect better than that of the molding compound 130. Such polymer 120 is, for example, epoxy resin or polyimide.

As mentioned above, the polymer 120 can effectively alleviate the stress at the periphery of the chip 114, especially at the four corners of the chip 114, so that the degree of delamination between the patterned circuit layers and the dielectric layers in the chip 114 can be reduced to improve the reliability of the chip 114.

In addition, though the price of such a polymer 120 is relatively higher than that of the molding compound 130, the manufacturing cost can still be well controlled because the polymer 120 is disposed merely at the periphery of the chip 114. Moreover, since the polymer 120 can cover all bonding pads 114b on the chip 114 and a portion of each wire 116 near the chip 114, the wires 116 can be well fixed onto the bonding pads 114b to prevent the “wire sweep’ problem.

### Third Embodiment

FIG. 2B illustrates a cross-sectional view of an electrical package structure incorporating a chip with polymer thereon according to the third embodiment of this invention. Referring to FIG. 2B, the electrical package structure 200 includes a package 210, a polymer 220 and a molding compound 230, wherein the package 210 includes a carrier 212, two chips 214, a spacer 218 and wires 216. The carrier 212 is a leadframe including a die pad 212a and leads 212b, for example. As compared with the electrical package structure 100 in the second embodiment of this invention, the electrical package structure 200 additionally includes a second chip 214 and a spacer 218. The spacer 218 is disposed between the two chips 214, and may be a dummy chip. The spacer 218 creates a distance between the two chips 214, so that the lower chip 214 can be bonded to the leads 212b through wire bonding. In addition, the two chips 214 can also be electrically coupled with each other by wire-bonding the bonding pads 214b thereon.

The polymer 220 can be disposed, possibly by using a dispenser, covering the whole periphery, two opposite edges or four corners of each of the two chips 214 and a portion of each of all or some wires 216 near the active surface 214a of the chip 214. The polymer 220 is preferably a stress buffer polymer like epoxy resin or polyimide, so that the stress at the periphery of each chip 214 is alleviated and the wire sweep problem is prevented. The other elements in the electrical package structure 200 and the materials and relative positions thereof can be the same as their analogs in the electrical package structure 100, and are therefore not described again.

### Fourth Embodiment

FIG. 2C illustrates a cross-sectional view of an electrical package structure incorporating a chip with polymer thereon according to the fourth embodiment of this invention. Referring to FIG. 2C, the electrical package structure 300 includes a package 310, a polymer 320, a molding compound 330 and an underfill 335, wherein the package 310 includes a carrier 312, two chips 314 and 318 and wires 316. The carrier 312 is a leadframe including a die pad 312a and leads 312b, for example. As compared with the electrical package structure 100 in the second embodiment of this invention, the electrical package structure 300 additionally includes a second chip 318, which has an active surface 318a with bonding pads 318b thereon. The bonding pads 318b on the chip 318 are connected with the contacts 312aa on the die pad 312a via bumps 340, so that the chip 318 can be electrically coupled with the die pad 312a. The underfill 335 is disposed between the chip 318 and the die pad 312a to reduce the stress in the bumps 340 that is generated due to long-term thermal expansion/shrinking. [Para 54]The polymer 320 can be disposed, possibly by using a dispenser, covering the whole periphery, two opposite edges or corners of the chip 314 and a portion of each of all or some wires 316 near the active surface 314a of the chip 314. The polymer 320 is preferably a stress buffer polymer like epoxy resin or polyimide, so that the stress at the periphery of the chip 314 is alleviated and the wire sweep problem is prevented. The other elements in the electrical package structure 300 and the materials and relative positions thereof can be the same as their analogs in the electrical package structure 100, and are therefore not described again.

### Fifth Embodiment

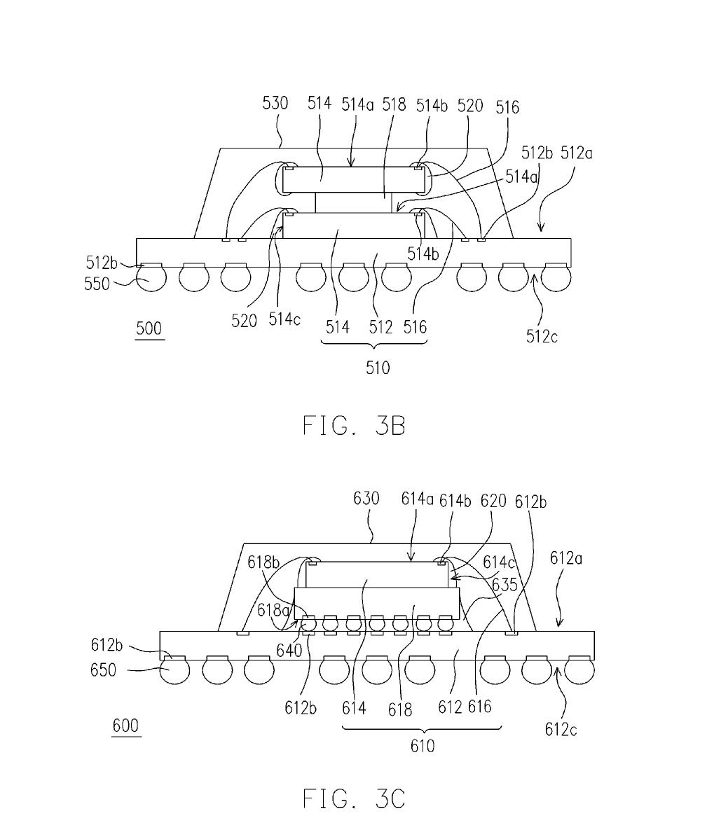

FIG. 3A illustrates a cross-sectional view of an electrical package structure incorporating a chip with polymer thereon according to the fifth embodiment of this invention. Referring to FIG. 3A, the electrical package structure 400 includes a package 410, a polymer 420 and a molding compound 430, wherein the package 410 includes a carrier 412, a chip 414 and wires 416. The carrier 412 is, for example, a circuit substrate having two surfaces 412a and 412c with contacts 412b thereon, wherein the contacts 412b on the surface 412c are disposed with solder bumps 450 so that the chip 414 can electrically communicate with external circuits.

The polymer 420 can be disposed, possibly by using a dispenser, covering the whole periphery, two opposite edges or corners of the active surface 414a and a portion of each of all or some wires 416 near the active surface 414a of the chip 414. The polymer 420 is preferably a stress buffer polymer like epoxy resin or polyimide, so that the stress at the periphery of the chip 414 is alleviated and the wire sweep problem is prevented. The other elements in the electrical package structure 400 and the materials and relative positions thereof can be the same as their analogs in the electrical package structure 100, and are therefore not described again.

### Sixth Embodiment

FIG. 3B illustrates a cross-sectional view of an electrical package structure incorporating a chip with polymer thereon according to the sixth embodiment of this invention. Referring to FIG. 3B, the electrical package structure 500 includes a package 510, a polymer 520 and a molding compound 530, wherein the package 510 includes a carrier 512, two chips 514, a spacer 518 and wires 516. As compared with the electrical package structure 400 in the fifth embodiment of this invention, the electrical package structure 500 additionally include a second chip 514 and a spacer 518, which is disposed between the two chips 514 and may be a dummy chip. The spacer 518 creates a distance between the two chips 514, so that the lower chip 514 can be coupled to the carrier 512 through wire bonding. In addition, the two chips 514 can also be electrically coupled with each other by wire-bonding the bonding pads 514b on the two chips 514.

The polymer 520 can be disposed, possibly by using a dispenser, covering the whole periphery, two opposite edges or corners of each of the two chips 514 and a portion of each of all or some wires 516 near the chip 514. The polymer 520 is preferably a stress buffer polymer like epoxy resin or polyimide, so that the stress at the periphery of each chip 514 is alleviated and the wire sweep problem is prevented. The other elements in the electrical package structure 500 and the materials and relative positions thereof can be the same as their analogs in the electrical package structure 400, and are therefore not described again.

### Seventh Embodiment

FIG. 3C illustrates a cross-sectional view of an electrical package structure incorporating a chip with polymer thereon according to the seventh embodiment of this invention. Referring to FIG. 3C, the electrical package structure 600 includes a package 610, a polymer 620, a molding compound 630 and an underfill 635, wherein the package 610 includes a carrier 612, two chips 614 and 618 and wires 616. The carrier 612 has two surfaces 612a and 612c with contacts 612b thereon. As compared with the electrical package structure 400 in the fifth embodiment, the electrical package structure 600 additionally includes a second chip 618, which has an active surface 618a with bonding pads 618b thereon. The bonding pads 618b on the chip 618 are connected with contacts 612b on the carrier 612 via bumps 640, so that the chip 618 can be electrically coupled with the carrier 612 to communicate with external circuits. The underfill 635 is disposed between the second chip 618 and the carrier 612 to reduce the stress in the bumps 640 that is generated due to long-term thermal expansion/shrinking.

The polymer 620 can be disposed, possibly by using a dispenser, covering the whole periphery, two opposite edges or corners of the active surface 614a of the chip 614 and a portion of each of all or some wires 616 near the chip 614. The polymer 620 is preferably a stress buffer polymer like epoxy resin or polyimide, so that the stress at the periphery of the chip 614 is alleviated and the wire sweep problem is prevented. The other elements in the electrical package structure 600 and the materials and relative positions thereof can be the same as their analogs in the electrical package structure 400, and are therefore not described again.

According to the above second to seventh embodiments of this invention, this invention can be widely applied to various package structures including wire-bonding package structures, wire-bonding/flip-chip package structures and multi-chip package structures, etc. In a multi-chip package structure, the chips may also be electrically coupled with each other by wire-bonding their bonding pads. Moreover, the above package is not restricted to use a leadframe or a circuit substrate to carry the chip, and may alternatively use a printed circuit board (PCB), a glass substrate, an undiced wafer or any other type of carrier to carry the chip. The effects of them are similar to those of the carriers described in the embodiments, and are therefore not mentioned here.

As mentioned above, the chip with polymer thereon and the electrical package structure including the same of this invention can be applied to wire-bonding package structures. In the electrical package structure including a chip with polymer thereon of this invention, a polymer that is preferably a stress buffer polymer like epoxy resin or polyimide is disposed at the periphery of the chip. Therefore, the stress at the periphery of the active surface of the chip, especially the stress at the periphery of the low-k dielectric layers in the chip, can be reduced to maintain the performance of the electrical package structure in long-term use. Moreover, since the stress at the periphery of the active surface is reduced, the degree of delamination between the patterned circuit layers and the dielectric layers can be reduced to improve the reliability of the electrical package structure. Furthermore, the polymer covers the bonding pads of the chip and a portion of each wire near the chip, so that the wires can be firmly fixed onto the bonding pads without the wire sweep problem. In addition, since the applied amount of the stress buffer polymer is much less than that of the molding compound, the manufacturing cost can be well controlled to make a balance between the stress buffer effect and the cost.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. An electrical package structure, incorporating a chip with polymer thereon and comprising at least:
a package, comprising:
a carrier;
a chip having an active surface, disposed on the carrier; and
a plurality of wires electrically connecting the chip and the carrier;
a polymer, disposed at periphery of the active surface of the chip extending to sidewalls of the chip; and
a molding compound covering the chip, the wires and the polymer.

2. The electrical package structure of claim 1, wherein the polymer further covers a portion of each wire near the active surface of the chip.

3. The electrical package structure of claim 1, wherein the polymer further covers a portion of the carrier.

4. The electrical package structure of claim 1, wherein the polymer is shaped as a ring covering whole periphery of the active surface of the chip.

5. The electrical package structure of claim 1, wherein the polymer is shaped as strips covering two opposite edges of the active surface of the chip.

6. The electrical package structure of claim 1, wherein the polymer is shaped as a plurality of pieces covering four corners of the active surface of the chip.

7. The electrical package structure of claim 1, wherein the carrier comprises a leadframe or a circuit substrate.

8. The electrical package structure of claim 1, wherein the polymer comprises a stress buffer polymer.

9. The electrical package structure of claim 8, wherein the stress buffer polymer comprises epoxy resin or polyimide.
